(19) United States
(12) Patent Application Publication
(10) Pub. No.: US 2024/0188312 A1
(43) Pub. Date: Jun. 6, 2024

(54) DIRECT PLASMONlC PHOTOVOLTAIC CELLS WITH INVERTED ARCHITECTURE

(71) Applicant: PEAFOWL PLASMONICS AB, Uppsala (SE)

(72) Inventors: Jacinto SÁ, Uppsala (SE); Cristina PAUN, Uppsala (SE); Fei PENG, Täby (SE); Laia CAPDEVILA, Uppsala (SE); Mohamed Ahmed QENAWY ABDELLAH, Uppsala (SE)

(73) Assignee: PEAFOWL PLASMONICS AB, Uppsala (SE)

(21) Appl. No.: 18/285,960

(22) PCT Filed: Apr. 11, 2022
(86) PCT No.: PCT/EP2022/059607

§ 371 Date: Oct. 6, 2023

(30) Foreign Application Priority Data
Apr. 12, 2021 (EP) 21020201.6

(51) Int. Cl. H10K 30/40; H10K 30/85

(52) U.S. Cl. CPC H10K 30/40; H10K 30/85

(57) ABSTRACT

A direct plasmonic photovoltaic cell (1) and a method of manufacturing such a photovoltaic cell is proposed. The photovoltaic cell (1) comprises: a first conductive substrate (2): a layer of a p-type semiconductor as a Hole Transporting Layer HTL (3): a layer of metal plasmonic nanoparticles (41. 42): a layer of an n-type semiconductor as an Electron Transporting Layer ETL (5); and a second conductive substrate (6). The HTL (3) is in direct physical contact with the first conductive substrate (2) and the second conductive substrate (6) is in direct physical contact with the ETL (5).

### TECHNICAL FIELD

The present disclosure relates to a method of obtaining a direct plasmonic photovoltaic cell with inverted architecture using low temperature methods and a direct plasmonic photovoltaic cell with inverted architecture obtainable by said method.

### BACKGROUND

A photovoltaic system is a system using the process of light conversion into electricity. The light may come from the sun or any artificial source. A known example of a photovoltaic cell is a solar cell, wherein solar light is converted into electricity, which has had an increased interest in the last years.

There exist many different kinds of conventional photovoltaics (solar cells), among which silicon cells are the most well-known, but there are also organic solar cells, thin-film solar cells (e.g. CIGS, CdTe), perovskite solar cells, etc. Direct plasmonic solar cells are the latest photovoltaic technology. They differ from all others in the way it absorbs light and creates electrical charges.

In conventional photovoltaic technologies, when a photon is absorbed by the active material, a certain amount of energy is used up to excite an electron from an occupied electronic level to an empty level, and that electron becomes responsible for the current that the cell generates. For a given material, a specific amount of energy is needed to excite (“kick out”) an electron, normally labelled as energy gap or bandgap. If the photon has less energy than needed, no electron will be excited. If the photon has excess energy, the excess energy is lost as heat.

A special type of conventional photovoltaics is the type called plasmonic-enhanced solar cell. These are regular solar cells that use plasmonic nanoparticles to scatter light or enhance the light absorption of the active material.

By contrast, in direct plasmonic solar cells, the energy conversion happens directly on the plasmonic nanoparticles, which are, in fact, the light absorbers, or active material. Direct plasmonic solar cells rely on the plasmon electron resonance mechanism. Instead of each photon exciting one specific electron, each photon contributes to the collective excitation of electrons in the material (resonance) that produce the current. This mechanism allows for all energy of the photon to be converted to electricity. No excess energy that is lost. There is a lower limit for the photon energy for conversion to occur (to produce a cell voltage), but it is typically lower than for other types of solar cells.

The use of plasmonic electronic resonance for energy conversion enables a much more efficient conversion, since more energy can be converted from the same number of photons. This means that less light must be captured to produce the same amount of electricity.

In the plasmon electron resonance mechanism, loosely bonded valence electrons in the metal nanoparticles are heated and create a hot electron gas. The dephasing and decoherence of the electron hot gas via the Landau damping mechanism leads to the creation of electrical hot carriers, i.e. hot electrons and holes. Conceptually, plasmonic nanostructures could be used directly in solar cells, but the photo-generated electron-hole pairs are short-lived (a few fs). This makes it problematic to draw current from such a device. Thus, to increase charge separation lifetime, the charge carriers can be confined to spatially separated sites where reactions will take place, e.g., by transferring them to a semiconductor (analogous to dye-sensitized solar cells). The hot electrons have sufficient energy to be injected into the conduction band of an Electron Transporting Layer (e.g. TiO₂), which significantly extends their lifetime.

Thus, to make a photovoltaic (solar cell) device, the hot electrons are transferred to an ETL material and the hot holes are transferred to a Hole Transporting Layer (HTL). The electrical charges are subsequently extracted by conductive electrodes.

Plasmonic nanomaterials have another significant advantage when used as light absorbers, namely they absorb at least tenfold more photons than other light absorbers, providing versatility in design and placement (outdoor and indoor). This new mechanism enables the development of a novel type of photovoltaic solar cells that are highly transparent and colourless.

Previously, direct plasmonic photovoltaic cells have been developed comprising a layer of silver nanospheres that capture light from 380-450 nm, sandwiched between a TiO₂ ETL layer and a HTL. The electrical charge is extracted by two conductive electrodes: a Fluorine doped Tin Oxide (FTO) glass in contact with the ETL and an AZO transparent back contact, on top of the HTL. The method of producing includes depositing the TiO₂ layer on the FTO glass by spray pyrolysis at 500° C. followed by annealing at 500° C. and loading of the Ag nanospheres. Subsequently, an HTL is deposited by spin coating using an organic solvent and the back contact is then added by sputtering. In this way, a transparent solar cell with a current power output sufficient to power electrochromic dynamic glass, IoT devices and low power displays is achieved.

However, such methods are demanding in terms of energy consumption, scalability, and suitability of chemical agents. In terms of energy consumption, there are two significant energy demanding steps, namely spray pyrolysis deposition and annealing of ETL. In terms of unsuitable chemical usage, during the deposition of the HTL, the integrity of the Ag nanoparticles needs to be preserved, which limits considerably the solvents that can be used to process the material. Moreover, the deposition of the HTL is done be spin coating, which is not scalable. The solvent also limits the range of plasmonic shapes that can be used to nanospheres, which limits light absorption and consequently output power.

Thus, it is desired to increase the direct power generation performance, while ensuring high transparency and colourless nature of the cells, for example so that they can be integrated into architectural glazing. Moreover, to comply with UN sustainable goals 7 (affordable and clean energy) and 12 (responsible consumption and production), the direct plasmonic solar cells must be produced using low energy manufacturing, sustainable chemical formulations and achieve higher performance.

### Object

It is one aim of the proposed technology to provide a method of obtaining a direct plasmonic photovoltaic cell with that is easy to be reproduced, uses low energy (no high temperature) and sustainable chemical formulations. Further, the method may be used to obtain direct plasmonic photovoltaic cells with inverted architecture that produce more power than other known direct plasmonic photovoltaic cells and can have a high transparency and are colourless at the same time. It is also an aim to provide a direct plasmonic photovoltaic cell obtained by said method.

### SUMMARY

According to a first aspect of the proposed technology, a method of obtaining, or manufacturing, a direct plasmonic photovoltaic cell is provided. The method comprises the steps of: a) depositing a Hole Transporting Layer (HTL) on a first conductive substrate; or first conductive layer; b) loading metal nanoparticles on the hole transporting layer to form a layer of metal plasmonic nanoparticles; c) depositing an Electron Transporting Layer (ETL) on the layer of metal plasmonic nanoparticles; and d) depositing a second conductive substrate, or second conductive layer, on the ETL. It is understood that the steps are performed in the listed order.

According to a second aspect of the proposed technology, a direct plasmonic photovoltaic cell is provided that comprises:—a first conductive substrate, or first conductive layer;—a layer of a p-type semiconductor as, or forming, a Hole Transporting Layer (HTL);—a layer of metal plasmonic nanoparticles;—a layer of an n-type semiconductor as, or forming, an Electron Transporting Layer (ETL); and—a second conductive substrate, or a second conductive layer.

It is understood that the substrates and layers are arranged in the listed order. It is further understood that terms “conductive substrate” and “conductive layer” are mutually interchangeable throughout these specifications. Worded differently the HTL may be between the first conductive substrate and the layer of metal plasmonic particles, the layer of metal plasmonic particles may be between the ETL and the HTL, and the ETL may be between the second conductive substrate and the layer of metal plasmonic particles. The direct plasmonic photovoltaic cell may be manufactured, or obtained, by the method according to the first aspect of the proposed technology.

The first conductive substrate may be, or form, a front contact. The second conductive substrate may be, or form, a back contact. A “contact” is understood as an element by which a current can be extracted from the photovoltaic cell. It is understood that the layer of metal plasmonic nanoparticles as such forms, or constitutes, an active photovoltaic material.

The metal nanoparticles may have non-spherical shapes. The layer of metal plasmonic nanoparticles may have at least two different shapes. Worded differently, the layer of metal plasmonic nanoparticles may comprise metal nanoparticles having at least two different shapes. The shapes may be selected from triangular prism, pyramid, cube, urchin like, or star like. If the layer of metal plasmonic nanoparticles has metal nanoparticles of two different shapes, one of the shapes may be spherical. The shapes of the nanoparticles are further discussed below.

In both aspects of the proposed technology the photovoltaic cell has an inverted architecture. In an inverted architecture, the HTL has been provided, or deposited, before the ETL in the manufacturing. This has significant advantages, which are explained below in relation to the discussion on the deposition of the HTL. The first conductive substrate may be thicker than the second conductive substrate. This means that the substrate closest to the ETL is thinner than the substrate closest to the HTL, which is advantageous in the manufacturing as it allows for a greater range of available p-type semiconductor materials.

The photovoltaic cell may be transparent. It may have an absorption that is less than 58. It may have a reflectance that is less than 108. It may have a total transmittance that is greater than 80%. For the indicated limits, the incident light is understood to be at a right angle to the photovoltaic cell.

The term “transparent” is used here in its broadest sense, meaning the quality an object or substance has when you can see through it, or when it does not significantly influence the perception of the underlying material. Different degrees of transparency are required depending on the intended use of the solar cells disclosed herein. For example, a high degree of transparency is desired when the solar cells are incorporated on window glass, and a lower degree of transparency is adequate when incorporated on other building materials.

The term “colourless” as used here, for example in relation to a layer, system or device, refers to a colour-neutral layer or device that does not have a distinguishable colour, as measured using the CIE 1931 RGB colour space developed by the International Commission on Illumination (CIE) in 1931.

The first conductive substrate may be a transparent glass material with a conductive layer on one of the sides or of a conductive polymer. Preferred examples of transparent glass material are Fluorinated Tin Oxide (FTO), Indium Tin Oxide (ITO), Aluminium doped Zinc Oxide (AZO) or Indium doped Zinc Oxide (IZO). The first conductive substrate may be a conductive polymer substrate. It may be either a polymer substrate with a conductive layer on one side, a substrate made of a conductive polymeric material, such as an intrinsically conducting polymer, or a substrate made of a conductive thermoplastic composite material.

The term “p-type semiconductors” which is used herein has the same meaning as “hole transporting layer (HTL)” and refers to semiconductor materials in which holes are the majority carriers, or positively charged carriers, and electrons are the minority carriers.

The HTL may comprise, or the p-type semiconductor may be selected from, include CuSCN, AgSCN, CuI, CuBr, PEDOT-PSS (poly (3,4-ethylenedioxythiophene) polystyrene sulfonate), Spiro: OMe TAD (2,2′, 7,7′-Tetrakis [N, N-di (4-methoxyphenyl) amino]-9,9′-spirobifluorene), PTAA (Poly [bis (4-phenyl) (2,4,6-trimethylphenyl) amine), CuXO₂ (wherein X is for example Cr, B, Al, Ga, In, Sc, Fe), and combinations thereof. Preferably, the HTL is CuSCN or AgSCN.

The HTL may have an average thickness of about 500 nm or less, preferably 250 nm or less, more preferably 150 nm or less, e.g. 120 nm, 100 nm, 50 nm or less. The HTL may be transparent. The thickness of the HTL may be determined by Scanning Electron Microscopy (SEM). Preferably, the HTL is transparent and colourless.

The HTL may be continuous. This means that there are no holes or gaps in the layer, such as pin holes. The HTL may be a solid layer. For example, this can be achieved through electrodeposition. Alternatively, the HTL may be a multilayer structure of p-type semiconductor particles. The particles may be nanoparticles. It is understood that in a multilayer structure, particles are deposited on top of one another and there is a particle-to-particle interaction, and possibly also a particle-to-particle adhesion.

Preferably, there are no molecular linkers between the HTL and the first conductive substrate. The HTL may be in direct mechanical contact, or direct physical contact, with the first conductive substrate. Worded differently, the HTL may be deposited directly onto the first conductive substrate. This means that the layer interacts directly with one another and that there cannot be any molecular linkers between the HTL and the first conductive substrate. If the HTL is a solid layer, the HTL then interacts directly with the first conductive substrate. If the HTL is a multilayer structure of p-type semiconductor particles, the semiconductor particles closest to the first conductive substrate are then in direct contact, or interacts directly, with the same. This means that there cannot be any molecular linkers between the HTL and the first conductive substrate.

In the known methods of manufacturing direct plasmonic photovoltaic cells, the HTL is deposited on top of the metal nanoparticles, which have been loaded on the ETL. The deposition of the HTL is subject to limitations due to the fragility of the nanoparticles. In order to preserve the integrity of the metal nanoparticles, the solution pH must be kept around neutral, which limits the use of water-based formulations and solvents that can be used to process the material.

In addition, only sphere shapes may be employed for the nanoparticles, as they are more robust and resistant to further processing in the presence of a solvent. This limits the absorption capacity of the cell, as will be explained below.

According to the proposed technology, the HTL is deposited before the formation of the layer of metal plasmonic nanoparticles, which allows a greater range of solvents to be used, which includes water. The use of water-based solvents enables more sustainable, processable and scalable manufacturing methods, like printing or spraying. Having the HTL deposited before the ETL brings advantages to the process, both in terms of reducing energy and use of sustainable chemical formulations. This is because there are fewer suitable materials for the HTL and solvents that can be deposited on top of the plasmonic nanoparticles without affecting the integrity of the latter. In contrast, it is relatively easy to find materials for the ETL that can be processed at low temperatures and deposited on top of plasmonic nanoparticles using sustainable solvents (e.g. water-based) at an adequate pH. The proposed order of deposition allows for transparent HTLs that can be made from water-based solutions and annealed at temperatures below 100° C., or below 135ºC, without generating pinholes.

A pinhole free first layer is essential to obtain a good performing solar cell device. Pinholes negatively affect three performance parameters of a solar cell, namely the short-circuit photocurrent, open-circuit voltage and fill factor. Pinholes can originate from an uneven conductive substrate and an ununiform coverage of the deposited layer, which is typically avoided by depositing thick layers. However, this has the disadvantage of a decrease in the overall transparency. Additionally, to ensure a good conductivity of a thick deposited layer, it must be annealed at high temperature (>300° C.), which makes them prone to cracks and pinhole formation. According to the proposed method, thin and pinhole free HTL may be obtained at relatively low temperatures, increasing the overall solar cell transparency and reducing energy consumption.

Possible methods of deposition of the HTL onto of the first conductive substrate include, but are not limited to electrodeposition, spray-coating, inkjet printing, slot-die printing, screen-printing, drop-casting, spin-coating, dip-coating, atomic layer deposition, sputtering or any other way that allows the formation of continuous HTL. Preferably, the deposition is at a temperature of 100° C. or below, or of 135° C. or below, which is a relatively low temperature. Preferably, the HTL is deposited by spraying or printing.

Preferably, the HTL is deposited on the first conductive substrate without forming molecular linkers between them. The deposition of the HTL may establish a direct mechanical, or physical, contact between the HTL and the first conductive substrate. The HTL may be deposited directly onto the first conductive substrate. Worded differently, the method comprises the step: a) depositing a HTL on a first conductive substrate with, or establishing, a direct mechanical, or direct physical, contact between the HTL and the first conductive substrate.

Preferably, the HTL is deposited on the first conductive substrate by electrodeposition, for example by electroplating. Alternatively, depositing a HTL may comprise: a.1) applying a layer of a first ink on the first conductive substrate; and a.2) processing the layer of the first ink to form the HTL. For example, the processing may comprise drying and/or curing.

The layer of the first ink may be continuous. The first ink may comprise p-type semiconductor particles, which may be nanoparticles. It may further comprise a solvent and/or a binding agent, such as a curable resin. The solvent may be removed in the processing step and the binding agent may be cured in the curing step.

The layer of the first ink may be applied by spraying, or printing. For example, it may be applied by spray-coating, inkjet printing, slot-die printing, or screen-printing. The layer of the first ink may be configured to form a multilayer structure of p-type semiconductor particles subsequent to the processing of the layer of the first ink. The p-type semiconductor particles closest to the first conductive substrate (2) may interacting directly with the first conductive substrate (2). For example, the concentration of p-type semiconductor particles and the thickness of the layer of the first ink may be selected such that the p-type semiconductor particles are arranged in at least three layers.

Depositing the HTL may be performed at a temperature of 100° C. or below, or of 135° C. or below. For example, the drying and/or curing the layer of the first ink may encompass heating the layer of the first ink to a temperature of 100° C. or below, or of 135° C. or below,.

An ink is generally understood as a solution that can be processed to make a continuous layer. It is understood to encompass a liquid having components, such as nanoparticles, binding agents, resins, surfactants, and dispersant agents, suspended or solved in a carrier liquid or solvent. For example, when using CuSCN and AgSCN, the ink may be composed only of these compounds and the solvent. No binding agents or resins are necessary. For practical reasons, some formulations also need to have a surfactant or a dispersant agent to adjust the formulation viscosity and improve stability.

Any metal nanoparticle may be used in the layer of metal nanoparticles having any geometrical shape, as long as it provides optical absorption in the optical range defined as electromagnetic spectrum ranging from UV to near Infrared (300-1200 nm), measured by UV-Vis optical absorption and reflectance.

Preferably, the nanoparticles are less than 200 nm in size irrespective of their geometrical shape, in order to further decrease light scattering and reflection. Particle size according to the proposed technology is assessed by Dynamic Light Scattering (DLS).

The metal nanoparticles may have at least two different geometrical shapes selected from sphere, cube, triangular prism, pyramid, urchin like, and star like. Preferably, the metal nanoparticles have sphere and prism geometrical shapes. When different geometrical shapes of metal nanoparticles are present, the absorption of light is significantly increased. This is because optical absorption of the nanoparticles changes with the shapes. Silver nanospheres may absorb light in a range from 380 to 450 nm. By adding other shapes, like triangular prism nanoparticles, the optical absorption may be expanded to encompass the electromagnetic spectrum of up to 1200 nm.

The light absorption may also change with the size of the nanoparticles. For example, silver nanoparticles with a triangular prism shape having a thickness of 5-10 nm and base sides with a length of about 20 nm may absorb light in a range from 400 to 600 nm. With a length of about 30 nm they may absorb light in a range from 500 to 650 nm, and with a length of about 50 nm they may absorb light in a range from 550 to 800 nm.

The light absorption may be increased by modifying only the size of a nanoparticle and not the geometrical shape. However, increasing the size may result in a reduced plasmonic effect and an increased reflectance, which leads to a drop in the effectiveness of the cell. If instead different geometrical shapes having similar sizes are used, the optical absorption may be enhanced with maintained plasmonic effect.

The proportion between the spheres and the prisms nanoparticles can be selected based on the desired light source spectrum and the desired level of transparency. For example, it has been found that in order to utilize light corresponding to the solar spectrum, approximatively equal amounts of nanospheres and triangular prisms may be used.

The metal nanoparticles may be selected from the group consisting of copper, gold, silver or aluminium. Worded differently, the metal nanoparticles may be copper, gold, silver or aluminium nanoparticles. Preferably, the metal nanoparticles are silver nanoparticles.

The layer of nanoparticles may be formed as a sub-monolayer, wherein the nanoparticles are situated sparsely from each other, preferably at a distance of at least 3 nm from each other. Worded differently, the layer of metal plasmonic nanoparticles may be, or comprise, a sub-monolayer. It has been found that this gives a low interference in the plasmonic effect of the individual nanoparticles.

The concentration of nanoparticles in a sub-monolayer may be between 10-20% of a compact, or continuous, monolayer. It has been found that this typically results in photovoltaic system that is colourless or has high transparency.

The layer of nanoparticles may have a thickness in the range of about 15 to about 250 nm. For example, the thickness can be measured by a SEM. Worded differently, the size, or maximum extension, of a nanoparticle may be in the range of 15 to 250 nm.

The metal nanoparticles may be synthesized using a reducing agent and a stabilizing agent. Worded differently, in the disclosed method, the metal nanoparticles may be subjected to, or modified with, a reducing agent and/or a stabilizing agent. Examples of reducing agents include NaBH₄, N₂H₄, ascorbic acid, betanin, polyols for example ethylene glycol, di-ethylene glycol, triethylene glycol, tetraethylene glycol, polyethylene glycol. Examples of stabilizing or growth-limiting agents include betanin, polyvinylpyrrolidone, polyvinyl acetate, polyols such as for example ethylene glycol, diethylene glycol, triethylene glycol, tetraethylene glycol polyethylene glycol or ascorbic acid. The reducing agent may be selected from this list. Ascorbic acid may be used as the stabilizing agent.

The layer of metal plasmonic nanoparticles may comprise first molecular linkers that links the metal nanoparticles to the HTL. If the HTL is a multilayer structure of p-type semiconductor particles, the first molecular linkers may link the metal nanoparticles to the p-type semiconductor particles. The first molecular linkers may form a sub-monolayer.

The layer of metal plasmonic nanoparticles may comprise second molecular linkers that link the metal nanoparticles to the ETL. The second molecular linkers may form a sub-monolayer. It is understood that the molecular linkers link the nanoparticles to the to the HTL and the ETL by covalent bonds. Molecular linkers are extensively discussed in WO 2018/178153 A1, which contents is incorporated by reference.

In step b), the metal nanoparticles may be loaded onto the HTL by printing or spraying, for example by inkjet printing, screen-printing, drop-casting, spin-coating, dip-coating, spray-coating. The loading of the metal nanoparticles may form a sub-monolayer. Preferably, spray coating is used, or worded differently, the metal nanoparticles are loaded by spray-coating.

In the known methods of obtaining direct plasmonic photovoltaic cells, the metal nanoparticles are loaded on an ETL, followed by the deposition of the HTL. When depositing the HTL, solvents are used that may affect the integrity of the metal nanoparticles. For this reason, only nanoparticles with spherical shape are used, which are more robust and resistant.

According to the proposed technology, the deposition of the HTL is made before loading the nanoparticles, which allows for non-spherical nanoparticles to be used. The subsequent deposition of the ETL can be selected such that it does not affect the integrity of the non-spherical shapes, as is explained above.

Loading the metal nanoparticles on the HTL may comprise: b.1) applying a layer of a second ink on the HTL; and b.2) processing the layer of the second ink to form the layer of metal plasmonic nanoparticles. For example, the processing may comprise drying and/or curing.

The layer of the second ink may be continuous. It is understood that the second ink comprises the abovementioned metal nanoparticles.

The second ink may further comprise the abovementioned first molecular linkers, or it may be configured to link the metal nanoparticles to the HTL by first molecular linkers. As mentioned above, if the HTL is a multilayer structure of p-type semiconductor particles, the first molecular linkers may link the metal nanoparticles to the p-type semiconductor particles.

The second ink may further comprise the abovementioned second molecular linkers, or it may be configured to link the metal nanoparticles to the ETL by second molecular linkers.

The layer of the second ink may be applied by spraying or printing. For example, it may be applied by spray-coating, inkjet printing, slot-die printing, or screen-printing.

The term “n-type semiconductors” which is used has the same meaning as “electron transporting layer (ETL)” and refers to semiconductor materials in which electrons are the majority carriers and holes are the minority carriers.

Examples of suitable ETL materials include SnO₂, ZnO, TiO₂, doped ZnO (eg Al: ZnO, In: ZnO), SrTiO₃, BrTiO₃, Sb₂O₅, doped Sb₂O₅ (eg. Sn—Sb₂O₅) and combinations thereof. Preferably, the ETL materials are SnO₂ and ZnO, or, worded differently, the ETL is made of SnO₂ or ZnO.

The ETL may have a thickness of about 200 nm or less, preferably 150 nm or less, more preferably 120 nm or less, e.g. 100 nm, 80 nm, 50 nm or less. The ETL may be transparent. Preferably, the ETL is transparent and colourless. For example, the thickness of the ETL can be determined by a SEM.

The ETL may be continuous. This means that there are no holes or gaps in the layer, such as pin holes. The ETL may be a multilayer structure of n-type semiconductor particles. The particles may be nanoparticles. As mentioned above, in a multilayer structure, particles are deposited on top of one another and there is particle-to-particle interaction, and possibly also a particle-to-particle adhesion.

If the ETL is a multilayer structure of n-type semiconductor particles, the second molecular linkers may link the metal nanoparticles to the n-type semiconductor particles. The second molecular linkers may form a sub-monolayer.

In step c), the ETL may be deposited by spraying or printing, for example by spray-coating, spin-coating or inkjet printing. This may be at a temperature below 100° C., or, or below 135ºC, which is a relatively low temperature. Other possible methods of deposition of the ETL onto of the metal nanoparticles layer include but are not limited to screen-printing, slot-die printing, drop-casting, spin-coating, dip-coating, atomic layer deposition, sputtering or any other way that allows the formation of a continuous ETL. Preferably, this is at a temperature of 100° C. or below, or of 135° C. or below, which is a relatively low temperature.

The ETL may be deposited directly onto the layer of metal plasmonic nanoparticles. Depositing the ETL may comprise: c.1) applying a layer of a third ink on the on the layer of metal plasmonic nanoparticles; and c.2) processing the layer of the third ink to form the ETL. For example, the processing may comprise drying and/or curing.

The layer of the third ink may be continuous. The third ink may comprise n-type semiconductor particles, which may be nanoparticles. It may further comprise a solvent and/or a binding agent, such as a curable resin. The solvent may be removed in the drying step and the binding agent may be cured in the curing step.

The layer of the third ink may be applied by spraying or printing. For example, it may be applied by spray-coating, inkjet printing, slot-die printing, or screen-printing. The layer of the third ink may be configured to form a multilayer structure of the n-type semiconductor particles subsequent to the processing of the layer of the third ink. The concentration of n-type semiconductor particles and the thickness of the layer of the third ink may be selected such that the n-type semiconductor particles are arranged in at least three layers.

Depositing the ETL may be performed at a temperature of 100° C. or below, or of 135° C. or below. For example, the drying and/or curing of the layer of the third ink may encompass heating the layer of the third ink to a temperature of 100° C. or below, or of 135° C. or below.

As mentioned above, the second ink may comprise second molecular linkers, or be configured to link the metal nanoparticles to the ETL by second molecular linkers. If the ETL is a multilayer structure of n-type semiconductor particles, the second molecular linkers may link the metal nanoparticles to the n-type semiconductor particles.

The second conductive substrate, or the back contact, may be made of a sputtered conductive oxide like ITO, AZO, or IZO. Additionally, or alternatively, it may be made of a transparent glass material with a conductive layer on one of the sides or of a conductive polymer. Preferred examples of transparent conductive glass material are FTO, ITO, AZO, or IZO. Preferred examples of a conductive polymer substrate are a polymer substrate with a conductive layer on one side, a substrate made of a conductive polymeric material, such as intrinsically conducting polymer, or a substrate made of a conductive thermoplastic composite material.

Preferably, the second conductive substrate may comprise a mixture of Ag nanowires and a conductive oxide, or conductive oxides, for example SnO₂ or AZO, or conductive polymer, for example PEDOT-PSS, a mixture of Ag nanowires and a conductive polymer, or a mixture of graphene and conductive polymer. These can be integrated in a transparent and colourless solar cell.

Preferably, there are no molecular linkers between the second conductive substrate and the ETL. The second conductive substrate may be in direct mechanical, or physical, contact with the ETL. This means that the layers interact directly with one another and that there cannot be any molecular linkers between the second conductive substrate and the ETL. If the ETL is a multilayer structure of n-type semiconductor particles, the semiconductor particles closest to the second conductive substrate are in direct contact, or interacts directly, with the same. This means that there cannot be any molecular linkers between the ETL and the second conductive substrate.

The second conductive substrate may be sputtered or formed by sputtering. This allows for good electrical conductivity and a thin layer with good transparency. The second conductive substrate may be thinner than the first conductive substrate.

As described above, the second conductive substrate is deposited on top of the ETL in step e). Preferably, the second conductive substrate is deposited by sputtering. Preferably, the second conductive substrate is deposited on the ETL without forming molecular linkers between them. The deposition of the second conductive substrate may establish a direct mechanical, or physical, contact between the second conductive substrate and the ETL. Worded differently, the method comprises the step: e) depositing a second conductive substrate (6) on the ETL (5) with, or establishing, a direct mechanical contact, or direct physical contact, between the second conductive substrate and the ETL (5).

The second conductive substrate may be deposited directly onto the ETL. Alternatively, a second conductive substrate can be applied on the ETL, such as conductive glass or plastic. Preferably, a mixture of Ag nanowires and conductive oxides or conductive polymers is used as the second conductive substrate. The second conductive substrate may be deposited by slot-die coating. This avoids using the commonly used sputtering technique, which are costly in terms of energy and requires sophisticated machinery. Additionally, no vacuum is needed in the slot-die coating. Sputtering also has the disadvantage in the formation of shunt cells.

Further layers or compounds, such as molecular linkers, may be present between the layers depicted above. If other layers are present, the deposition thereof may be made by any of the methods described above, as long as the integrity of the metal nanoparticles or of the other layers is not affected.

As described above, the p-type semiconductor, or the HTL, and the metal nanoparticles may be covalently linked by means of a molecular linker. Similarly, the metal nanoparticles and the n-type semiconductor, or the ETL, may be covalently linked by means of a molecular linker.

A molecular linker should provide an excellent electronic coupling by good n-conjugated properties, rigidity and planarity. Preferably, molecules with selective reactive groups to each component should be used, for example carboxylic or phosphonic acid together with the p-type semiconductor, and amine or thiols together with the nanoparticles. Examples of suitable molecular linkers are given in the international application WO2018/178153 A1 and are incorporated herein by reference.

The plasmonic photovoltaic cell may comprise an insulating layer situated between the layer of metal nanoparticles and the ETL. The insulating layer may be configured for allowing tunnelling of electrons from the layer of metal nanoparticles to the ETL. Worded differently, the tunnelling may be from the layer of metal plasmonic nanoparticles to the ETL, or from second molecular linkers that links the metal nanoparticles to the insulating layer. The latter is further discussed below.

It is described above that the layer of metal plasmonic nanoparticles may comprise second molecular linkers that links the metal nanoparticles to the ETL. Instead, it may comprise second molecular linkers that links the metal nanoparticles to the insulating layer. These second molecular linkers may form a sub-monolayer. It is understood that the molecular linkers link the nanoparticles to the insulating layer by covalent bonds. The ETL may be in direct mechanical, or physical, contact with the insulating layer.

The second conductive substrate may be deposited directly onto the ETL. Instead of depositing the second conductive substrate on the ETL, the method may comprise: d) depositing an insulating layer on the ETL; and e) depositing a second conductive substrate (6) on the insulating layer.

As mentioned above, the second ink may comprise second molecular linkers, or be configured to link the metal nanoparticles to the ETL by second molecular linkers. Instead, the second molecular linkers may link the metal nanoparticles to the insulating layer.

The insulating layer may be composed of materials with a large energy difference between valence and conduction band, i.e. a large band gap, and no or very low electrical conductivity. The conduction band edge should be at 3.5 eV or less from the vacuum and the valence band should be 6.5 eV or more from the vacuum.

The insulating layer may be made of, or comprise, SiO₂, Al₂O₃, ZrO₂, tetraethyl orthosilicate (TEOS), (3-aminopropyl) triethoxysilane (APTES), (3-mercaptopropyl) triethoxysilane, aminophenyltrimetoxysilane, organophosphates (CₙH₂ₙ₊₁—PO (OH)₂), amino-organophosphates (H₂N—CₙH₂ₙ—PO (OH)₂), thiol-organophosphates (HS—C₂H₂ₙ—PO (OH)₂), organocarboxilates (CₙH₂ₙ₊₁—CO(OH)), amino-organocarboxilates (H₂N—CₙH₂ₙ₊₁—CO(OH)) or thiol-organocarboxilates (HS—CₙH₂ₙ₊₁—CO(OH)).

The insulating layer may have a thickness of 10 nm or less, preferably 1 nm or less, or more preferably 1 nm or less. When the thickness of the insulating layer is 10 nm or less, it is ensured that hot electrons are effectively transferred from the metal nanoparticles layer to the ETL by tunnelling through the insulating layer. The insulating layer may have a thickness that is greater than 0.5 nm. It has been found that if the thickness of the insulating layer is less than 0.5 nm, its insulating effect may not be achieved.

The photovoltaic cell may further comprise a support layer (X), or protective layer, covering the second conductive substrate. It is understood that the support layer (X) is next, or juxtaposed, to the second conductive substrate, and that the second conductive substrate is between the support layer and the first conductive substrate. This is particularly advantageous if the second conductive substrate has been sputtered, or formed by sputtering, which makes it sensitive to mechanical wear. The support layer (X) may have an outer adhesive surface. For example, the adhesive surface may be configured to attach the photovoltaic cell to a smooth surface, such as a glass pane or a plastic sheath. Worded differently, the support layer may be configured to adhere to a smooth surface.

The above-described method may further comprise: depositing, or providing, a support layer (X) on the ETL. The support layer (X) may have the properties described above.

In a further aspect of the proposed technology, a foil is provided comprising the direct plasmonic photovoltaic cell. The foil may be transparent. It may be flexible. It is understood that a foil is a thin sheet-like structure. It is further understood that the layers of the direct plasmonic photovoltaic cell are aligned, or extends parallel, with the foil. The thickness of the foil depends on the thickness of the layers.

The foil may be configured for electrically charging an electronic device or a building element. The electronic device may be a consumer electronic device, for example intended for everyday use. Preferably electronic device has a low electricity consumption. It may be an e-paper display, e-reader, internet of things device or sensor, smart device, smart watch, mobile phone, or tablet. The building element may be a window, a roof element, or a wall element.

### BRIEF DESCRIPTION OF THE DRAWINGS

Different embodiments and examples of the proposed technology will be described below with reference to the drawings:

FIG. 1 schematically shows a conceptual design of a direct plasmonic solar cell, according to an embodiment of the proposed technology, and

FIG. 2 represents a graph showing the changes of optical absorption with changes in plasmonic shape and size.

FIG. 3 is a flow chart illustrating an example of the manufacturing of a direct plasmonic solar cell.

FIG. 4 schematically shows a direct plasmonic solar cell resulting from the manufacturing described in relation to FIG. 3.

FIG. 5 is a flow chart illustrating another example of the manufacturing of a direct plasmonic solar cell.

FIG. 6 schematically shows a direct plasmonic solar cell resulting from the manufacturing described in relation to FIG. 5.

### DESCRIPTION

### Example 1

Silver metal nanoparticles were synthesized starting from the respective metal precursor, for example AgNO₃, a reducing agent, and a stabilizing agent. Examples of reducing agents and stabilizing agents are mentioned above. All reagents were purchased from Sigma-Aldrich/Merck and were of analytical quality.

The protocol presented in Dong, H., Chen, Y.-C., Feldmann, C. “Polyol synthesis of nanoparticles: status and options regarding metals, oxides, chalcogenides, and non-metal elements”, Green. Chem. 17, 4107-4132 (2015) was followed to make nanospheres. The protocol in Aherne, D., Ledwith, D. M., Gara, M. & Kelly, J. M. “Optical properties and growth aspects of silver nanoprisms produced by a highly reproducible and rapid synthesis at room temperature”, Adv. Funct. Mater. 18, 2005-2016 (2008) was followed to make triangular nanoprisms. The content of these two citations is incorporated by reference. Parameters were selected, such as the concentration of components, solvents, reaction temperature, and reaction time, in order to optimize the geometry of the nanoparticles and the size distribution.

If a linker was used, the pH of the Ag nanoparticle suspension is adjusted to 4-5 and the particles were coated with pABA (Sigma-Aldrich), which anchors to Ag surface via the —NH₂.

In different embodiments, gold, copper, and aluminium nanoparticles may be obtained starting from the respective metal precursor, for example CuSO₄ or CuCl₂ for copper nanoparticles or HAuCl₄ for gold nanoparticles.

A HTL of CuSCN having a thickness of 100 nm was obtained via electrodeposition of 12 mM of CuSO₄ and 12 mM KSCN. An ETL of Sno₂ having a thickness of 30 nm was obtained from SnO₂ colloidal solution with a 15% in H₂O colloidal dispersion. In a different embodiment, an ETL of ZnO having a thickness of 30 nm was obtained from inkjet dispersion from Sigma-Aldrich.

A first conductive layer of FTO glass was used having a thickness of 2 mm. The FTO glass was obtained from NSG-Pilkington.

As a second conductive layer, slot-die coated silver nanowires with a conductive oxide (SnO₂, AZO) or polymer (PEDOT-PSS) was used.

In a different embodiment, a second conductive layer of sputtered AZO with a thickness of 150-200 nm was used.

### Example 2

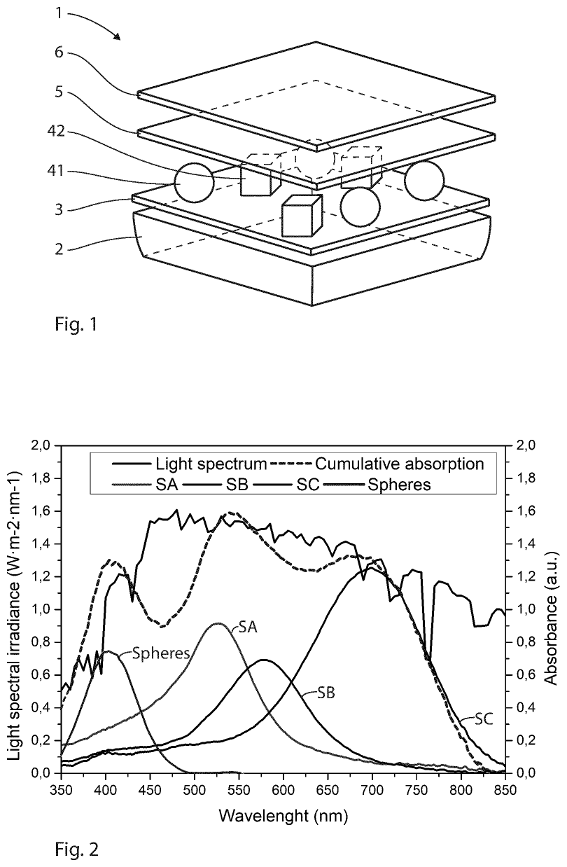

FIG. 1 shows an embodiment of a direct solar cell with inverted architecture. A CuSCN HTL 3 is deposited on top of a first conductive substrate 2 made of FTO glass. Silver nanoparticles having spherical shape 41 and cubic shape 42 are situated on top of the HTL 3 and below the ETL 5 made of SnO₂ or ZnO. The silver nanoparticles. In a different embodiment, the nanoparticles have other geometrical shapes, for example triagonal prisms. A back contact 6 made of a mixture of Ag nanowires the conductive oxide SnO₂ is placed on top of the ETL 5. In a different embodiment, the conductive oxide is AZO.

The described architecture allows for a more efficient absorption of light due to the different types of geometrical shapes of metal nanoparticles. The absorption properties of the silver nanoparticles are shown in FIG. 2. Spherical silver nanoparticles (Spheres) maintaining a plasmonic effect absorb light in a range from 380-450 nm. Silver nanoparticles (SA) with a triangular prism shape having a thickness of 5-10 nm and a triangular base with a side length of about 20 nm absorb light in a range 400 to 600 nm. If the nanoparticles (SB) instead have a triangular base with a side length of about 30 nm, they absorb light in the range 500 to 650 nm. If the nanoparticles (SB) instead have a triangular base with a side length of about 50 nm, they absorb light in the range 550 to 800 nm. Thus, by varying the shapes and sizes of the metal nanoparticles, a cumulative absorption (represented with a dotted line) can be obtained that better matches the light spectrum of the sun.

### Example 3

In one embodiment, a solar cell was obtained as described below. An FTO glass was cut into rectangular samples of 14 mm×24 mm. These dimensions were chosen to give some tolerance of the glass pieces for the final deposition steps and measurement. The samples were patterned by chemical etching. The long sides of each sample were taped (using 3M-Magic tape or Kapton) so that they covered around 2 mm on each end. The samples were covered with zinc powder (only a pinch was required). This was followed by adding drops of 2M HCl onto the samples to start an etching reaction. After approximatively 2 min the etching was complete and the etching solution was washed off with water, thus providing a first conductive substrate. The samples were further washed by sonication in 2% Hellmanex solution (diluted with DI water) for 30 min. Afterwards, the samples were washed by sonication in DI water for 15 minutes, followed by 15 minutes of IPA. The cleaning procedure is finished with a 15 min UV-Ozone treatment process.

An HTL of CuSCN was deposited on the first conductive substrate. The precursor solution for the copper thiocyanate (CuSCN) electrodeposition consisted of an aqueous solution of 12 mM copper sulphate (CuSO₄), 12 mM ethylene diaminetetra acetic acid (EDTA) and 12 mM potassium thiocyanate (KSCN). The sample was immersed in this solution acting as a working electrode with a platinum wire acting as a counter electrode and a silver/silver chloride (Ag/AgCl) electrode acting as reference. Films were formed by applying −0.455 V in three periods 20 s with 30 s at 0 V between the periods. When the deposition was finished, the sample was rinsed with distilled water and dried with N₂ gas. To remove pinholes a thin CuSCN layer (ca. 10 nm) was spin-coated (3000 rpm for 30 sec) on top of the electrodeposited layer using a CuSCN in 50% aqueous ammonia solution at a concentration 10 mg/mL, thus providing the HTL on the first conductive substrate.

A layer of metal nanoparticles is then loaded on the HTL. In this embodiment, silver spheres and triangular prisms were used. Silver nanospheres were synthesized from 0.8 ml Glycerol, 8.2 H₂O, 0.1 ml AgNO₃, and 0.5 ml Na-citrate, which were mixed in a microwave tube. After 30 min at 95° ° C., a solution of Ag nanoparticles was obtained. It was purified in centrifuge at 14.8 K rpm for 20 min. The nanoparticles were re-dispersed in 2 ml H₂O. Silver triangular nanoprisms were synthesized using a two-step method. In the first step a seed solution was synthesized and in the second step the seeds were grown into nanoprisms. The seed solution was produced mixing aqueous trisodium citrate (5 mL, 2.5 mM), aqueous poly (sodium styrenesulphonate) (PSSS) (0.25 mL, 500 mg/L), aqueous sodium borohydride (0.3 mL, 10 mM, freshly prepared) and aqueous silver nitrate (5 mL, 0.5 mM, 2 mL/min) under vigorous stirring. The resulting yellowish solution was stored in a refrigerator for the second step. To grow the nanoprisms, water (5 mL), aqueous ascorbic acid (75 μL, 10 mM), seed solution (various quantities to obtain different prism sizes, we used from 0.1-1 mL from the seeds stock solution) and aqueous silver nitrate (3 mL, 0.5 mM, 1 mL/min) were mixed under vigorous stirring. Once the addition of AgNO₃ was finished, aqueous trisodium citrate (0.5 mL, 25 mM) was immediately added to the mixture and stirred for around a minute. Samples were kept as prepared in the refrigerator for a minimum of 48 h before using them. The silver plasmonic nanoparticles were deposited on the HTL (CuSCN) as follows: pre-made silver spheres and prisms caped in molecular linkers (4-aminopyridine and p-aminobenzoic acid) were mixed and spray deposited at room temperature on top of the HTL. The nanoparticles Thus, a minimum of two silver nanoparticles shapes were used. The resulting sample was washed thoroughly using DI-H₂O and dried using Ar gas, thus providing layer of metal plasmonic nanoparticle on the HTL.

An ETL of SnO₂ was deposited on the layer of metal nanoparticles by spin coating. The solution consisted of Sn (IV) oxide nanoparticles in a 15% H₂O colloidal dispersion diluted 1:4 in water. The spin coating was performed at 3000 rpm for 30s. The resulting layer was annealed at 100° C. for 45 minutes. To remove pinholes on the deposited Sno₂ layer, a thin SnCl₂ layer (ca. 10 nm) was spin-coated at 3000 rpm for 30 sec. A SnCl₂ solution at a concentration 1 mg/mL was used. After deposition, the layer was annealed at 100° C. for 15 minutes to convert the SnCl₂ into SnO₂, thus providing the ETL on the layer of metal nanoparticles.

Silver nanowires (Ag NWs) from Sigma-Aldrich were deposited onto the ETL as a back contact for the solar cell by slot die coating. A solution of 1.2 wt % of Ag NWs (diameter×length=50 nm (±10 nm)×40 μm (±5 μm), 5 mg/mL in isopropyl alcohol) were dispersed in a solution of ethylene glycol (2 vol %) in isopropyl alcohol (98 vol %). A dispersant of 0.005 g/mL of D520 Nafion dispersion-alcohol based 1000 EW from Dupont was added to avoid Ag NWs aggregation. The gap between the slot-die coater and the solar cell was set at 0.05 mm and a shim plate was used with a thickness of 0.03 mm and a printing speed of 50 RPM. After depositing of Ag NWs, the sample was sprayed with a 6 wt % solution of SnCl₄·5H₂O. The sample was then dried and annealed at 80° C. for 15 minutes to increase connectivity between Ag NWs and to fill the gaps between the wires, thus providing a second conductive substrate on the ETL.

By following this procedure, a solar cell as presented in FIG. 1 was obtained, comprising silver nanoparticles with spherical and triagonal prism (not shown) shapes.

### Example 4

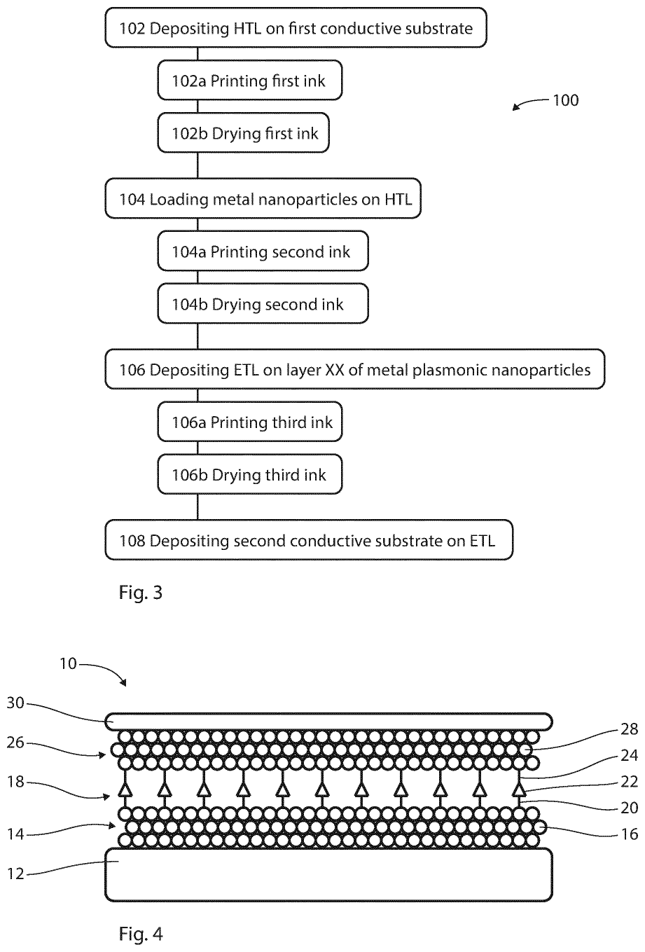

FIG. 3 is a flow chart illustrating the manufacturing 100 of a direct plasmonic solar cell. The resulting plasmonic solar cell 10 is schematically illustrated in FIG. 4. A transparent first conductive substrate 12 is provided. The first conductive substrate 12 is of FTO glass. In a first step, 102 a transparent and continuous Hole Transporting Layer (HTL) 14 is deposited on the first conductive substrate 12 by 102a printing a continuous layer of a first ink on the first conductive substrate 12, and 102b drying the layer of the first ink to form the HTL 14. The first ink comprises p-type semiconductor nanoparticles 16 of CuSCN suspended in a carrier liquid of DiMethyl Sulfoxide (DMSO). The p-type semiconductor nanoparticles 16 are arranged in a multilayer structure after drying, which establishes a particle-to-particle interaction and adhesion. There are also direct physical contact and interaction between the first conductive substrate 12 and the juxtaposed p-type semiconductor nanoparticles 16. There are no molecular linkers between the first conductive substrate 12 and the HTL 14.

In an alternative manufacturing, the HTL 14 is a solid layer provided by electrodeposition.

In a second step 104, prism-shaped metal nanoparticles 22 are loaded on the HTL 14 to form a layer 18 of metal plasmonic nanoparticles. The metal nanoparticles 22 are of silver. The metal nanoparticles 22 are loaded by 104a printing a continuous layer of a second ink on the HTL 14. The second ink comprises the metal nanoparticles 22, which are suspended in a carrier liquid of water. The second ink is then 104b dried to form the layer 18 of metal plasmonic nanoparticles. The concentration of metal nanoparticles 22 and the amount of printed second ink is such that a transparent sub-mono layer of the metal nanoparticles 22 is formed.

The second ink comprises first molecular linkers 20 that link the metal nanoparticles 22 to the p-type semiconductor particles 16 of the HTL 14. The first molecular linkers 20 are 4-aminopyridine. In another example, the first molecular linkers 20 are 4-mercaptopyridine. The second ink further comprises second molecular linkers 24 of p-aminobenzoic acid that link the metal nanoparticles 22 to an Electron Transporting Layer (ETL) 26, which is further described below.

In a third step 106, a transparent ETL 26 is deposited on the layer 18 of metal plasmonic nanoparticles by 106a printing a continuous layer of a third ink on the layer 18 of metal plasmonic nanoparticles and 106b drying the layer of the third ink to form the ETL. The third ink comprises n-type semiconductor nanoparticles 28 of ZnO suspended in a carrier liquid of isopropanol. The n-type semiconductor nanoparticles 28 are arranged in a multilayer structure after drying, which establishes a particle-to-particle interaction and adhesion. The second molecular linkers 24 link the metal nanoparticles 22 to the n-type semiconductor particles 28 of the ETL 26.

In a fourth step 108, a transparent second conductive substrate 30 is deposited on the ETL 26 by sputtering a solid layer of AZO on the ETL 26. This way, there is a direct physical contact and interaction between the second conductive substrate 30 and the closest of the n-type semiconductor nanoparticles 28. This means that there are no molecular linkers between the ETL 26 and the second conductive substrate 30.

### Example 5

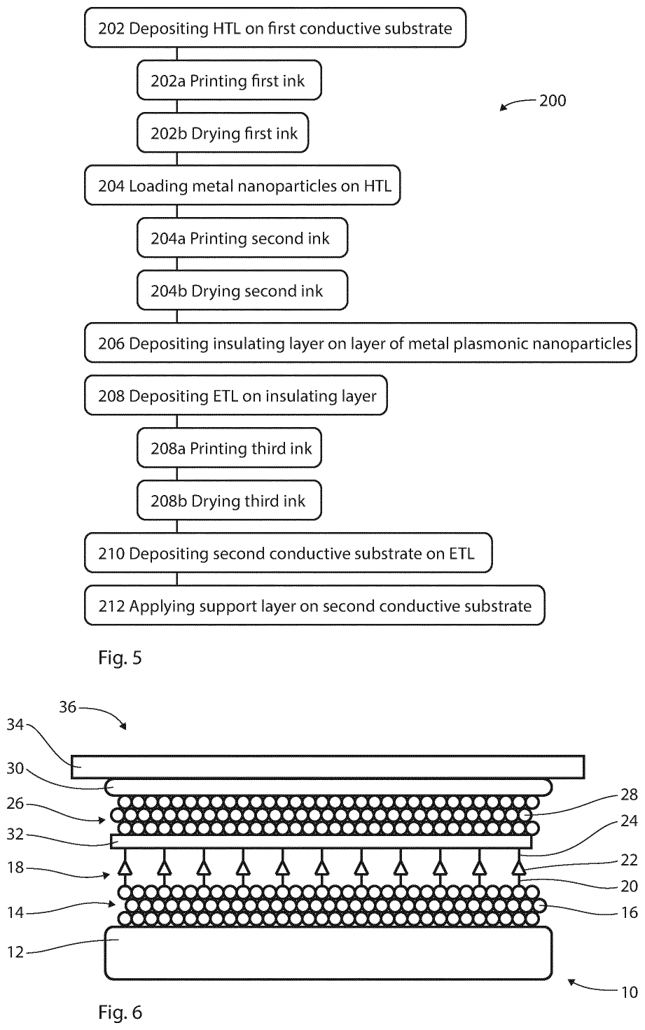

FIG. 5 is a flow chart illustrating the manufacturing 200 of a direct plasmonic solar cell. The resulting plasmonic solar cell (20) is schematically illustrated in FIG. 6. As in the previously described method outlined in FIG. 3, the manufacturing starts with a conductive substrate 12 of FTO. The first step 202 and second step 204 are the same as steps 102 and 104 in the previously described method. The only difference is in that the second ink comprises second molecular linkers of p-aminobenzoic acid that link the metal nanoparticles 22 to an insulating layer 32, which is further described below.

In a third step 206, a transparent insulating layer 32 of 3-aminopropyltriethoxysilane is deposited by slot-die coating on the layer 18 of metal plasmonic nanoparticles. In a fourth step 208, a transparent ETL 26 is deposited on the insulating layer 32 by 208a printing a continuous layer of a third ink on the insulating layer 32 and 208b drying the layer of the third ink to form the ETL 26. The third ink comprises n-type semiconductor nanoparticles 28 of ZnO suspended in a carrier liquid of isopropanol. The n-type semiconductor nanoparticles 28 are arranged in a multilayer structure after drying. The insulating layer 32 has an average thickness of 1 nm, which allows for an efficient tunnelling of electrons from the second molecular linkers 24 to the ETL 26.

In a fifth step 210, a transparent second conductive substrate 30 is deposited on the ETL 26 by sputtering a solid layer of AZO, corresponding to the fourth step 108 in the previously described method outlined in FIG. 3. In a sixth step 212, a transparent support layer 34 in the form of Poly (Methyl MethAcrylate) (PMMA) is applied on the second conductive substrate 30, thus forming a film 36 with the plasmonic solar cell 10.

1-15. (canceled)

16. A method for obtaining a direct plasmonic photovoltaic cell, the method comprising the steps of:
a) depositing a Hole Transporting Layer (HTL) on a first conductive substrate with a direct physical contact between the HTL and the first conductive substrate;
b) loading metal nanoparticles on the HTL to form a layer of metal plasmonic nanoparticles;
c) depositing an Electron Transporting Layer (ETL) on the layer of metal plasmonic nanoparticles; and
d) depositing a second conductive substrate on the ETL with a direct physical contact between the second conductive substrate and the ETL.

17. The method according to claim 16, wherein the photovoltaic cell is transparent.

18. The method according to claim 16, wherein the HTL is made of a material selected from the group consisting of CuSCN and AgSCN.

19. The method according to claim 16, wherein the HTL is deposited by a method selected from the group consisting of spraying and printing.

20. The method according to claim 16, wherein depositing the HTL comprises:
a.1) applying a layer of a first ink on the first conductive substrate, wherein the first ink comprises p-type semiconductor particles; and
a.2) processing the layer of the first ink to form the HTL;
wherein the layer of the first ink is configured to form a multilayer structure of p-type semiconductor particles subsequent to the processing with the p-type semiconductor particles closest to the first conductive substrate interacting directly with the first conductive substrate.

21. The method according to claim 16, wherein the metal nanoparticles are selected from the group consisting of copper, gold, silver, and aluminium.

22. The method according to claim 16, wherein the layer of metal plasmonic nanoparticles is a sub-monolayer.

23. The method according to claim 16, wherein the metal nanoparticles have at least two different shapes selected from the group consisting of triangular prism, pyramid, and urchin-shaped.

24. The method according to claim 16, wherein the metal nanoparticles are loaded by a method selected from the group consisting of spraying and printing.

25. The method according to claim 16, wherein the ETL is made of one of SnO₂ and ZnO.

26. The method according to claim 16, wherein the ETL is deposited by sputtering.

27. The method according to claim 16, wherein the second conductive substrate is made of a mixture of Ag nanowires and a conductive oxide.

28. A direct plasmonic photovoltaic cell comprising:
a first conductive substrate;
a layer of a p-type semiconductor as a Hole Transporting Layer HTL;
a layer of metal plasmonic nanoparticles;
a layer of an n-type semiconductor as an Electron Transporting Layer ETL; and a second conductive substrate;
wherein the HTL is in direct physical contact with the first conductive substrate, and the second conductive substrate is in direct physical contact with the ETL.

29. The direct plasmonic photovoltaic cell according to claim 28, wherein the HTL is a multilayer structure of p-type semiconductor particles, wherein the p-type semiconductor particles closest to the first conductive substrate interact directly with first conductive substrate.

30. A transparent foil for electrically charging an electronic device, wherein the foil comprises a direct plasmonic photovoltaic cell, comprising:
a first conductive substrate;
a layer of a p-type semiconductor as a Hole Transporting Layer HTL;
a layer of metal plasmonic nanoparticles;
a layer of an n-type semiconductor as an Electron Transporting Layer ETL; and
a second conductive substrate;
wherein the HTL is in direct physical contact with the first conductive substrate, and the second conductive substrate is in direct physical contact with the ETL.

31. The transparent foil according to claim 30, wherein the HTL is a multilayer structure of p-type semiconductor particles, and wherein the p-type semiconductor particles closest to the first conductive substrate interact directly with first conductive substrate.
